(19) United States
(12) Patent Application Publication
(10) Pub. No.: US 2014/0199822 A1
(43) Pub. Date: Jul. 17, 2014

(54) METHODS OF FORMING SEMICONDUCTOR DEVICE STRUCTURES INCLUDING AN INSULATIVE MATERIAL ON A SEMICONDUCTIVE MATERIAL, AND RELATED SEMICONDUCTOR DEVICE STRUCTURES AND SEMICONDUCTOR DEVICES

(71) Applicant: Kunal Shrotri, Boise, ID (US)

(72) Inventor: Kunal Shrotri, Boise, ID (US)

(73) Assignee: Micron Technology, Inc., Boise, ID (US)

(21) Appl. No.: 13/741,672

(22) Filed: Jan. 15, 2013

(51) Int. Cl. H01L 21/02; H01L 21/762

(52) U.S. Cl. CPC H01L 21/02345; H01L 21/76224
USPC 438/435; 438/473

(57) ABSTRACT

A method of forming a semiconductor device structure. The method comprises forming an insulative material on a semiconductive material, and microwave annealing at least an interface between the insulative material and the semiconductive material. Additional methods of forming a semiconductor device structure, and related semiconductor device structures and a semiconductor device are also described.

### FIELD

Embodiments of the disclosure relate to the field of semiconductor device design and fabrication. More specifically, embodiments of the disclosure relate to methods of forming semiconductor device structures including an insulative material on a semiconductive material, and to related semiconductor device structures and semiconductor devices.

### BACKGROUND

Insulative materials function as significant structural components of many integrated circuits. For example, silicon oxide materials may be used to facilitate data storage within memory devices of an integrated circuit. Volatile memory devices (e.g., dynamic random access memory (DRAM) devices), for instance, may use silicon oxide materials to provide charge retention within capacitors of memory cells. For binary data storage, a charged capacitor may be read as logical “1,” while a discharged capacitor may be read as logical “0.”

However, problems associated with forming insulative materials can reduce the performance and reliability of the semiconductor devices into which the insulative materials are incorporated. For example, forming a silicon oxide material on a silicon material can result in defects, such as interfacial charge traps, that can negatively impact the properties of semiconductor device structures and semiconductor devices including the silicon oxide material. To illustrate, if a silicon oxide material is to facilitate charge retention within memory cells of a volatile memory device, defects resulting from forming the silicon oxide material on a silicon material may cause current leakage through the silicon oxide material and induce variation in the retention time (i.e., the length of time that a memory cell may hold a charge before needing to be refreshed) of at least some of the memory cells. Such variable retention time (VRT) is problematic because, unless the volatile memory device is refreshed at a rate that is shorter than the minimum retention time of any of the memory cells under any conditions, data stored in the volatile memory device may be lost. However, identifying the shortest retention time of any of the memory cells, or even the conditions that cause the lowest retention time to occur, may not be feasible since volatile memory devices may comprise millions of individual memory cells. In addition, selecting an unduly short refresh time to account for potential variable retention times of individual memory cells is not an effective option because an unduly short refresh time means that circuitry performing the refresh operation will be inefficient (e.g., operating more frequently and consuming more power than may be necessary).

It would, therefore, be desirable to have improved methods of forming an insulative material such that the resulting insulative material may enable fabrication of semiconductor device structures and semiconductor devices having improved performance characteristics.

### BRIEF DESCRIPTION OF THE SEVERAL VIEWS OF THE DRAWINGS

FIGS. 1A and 1B are partial cross-sectional views illustrating different process stages and structures for a method of forming a semiconductor device structure in accordance with embodiments of the disclosure.

FIGS. 2A through 2F are partial cross-sectional views illustrating different process stages and structures for a method of forming a semiconductor device structure in accordance with additional embodiments of the disclosure.

FIG. 3 is a partial schematic view of a memory array in accordance with embodiments of the disclosure.

FIG. 4 is a diagrammatic block view of a memory device in accordance with embodiments of the disclosure.

### DETAILED DESCRIPTION

Methods of forming semiconductor device structures including an insulative material on a semiconductive material are disclosed, as are related semiconductor device structures and semiconductor devices. In some embodiments, forming a semiconductor device structure includes subjecting the semiconductor device structure to at least one microwave anneal process to anneal an interface between an insulative material and a semiconductive material. The microwave anneal process may efficiently reduce a defect density at the interface between the insulative material and the semiconductive material. The microwave anneal process may also create a more abrupt (e.g., distinct) boundary between the insulative material and the semiconductive material. In addition, the microwave anneal process may alleviate (e.g., reduce) problems associated with processes conventionally used to reduce a defect density at an interface between an insulative material and a semiconductive material. For example, the microwave anneal process of the disclosure may reduce deformation problems and material diffusion problems relative to thermal anneal processes conventionally used to reduce defect density. In some embodiments, the methods of the disclosure may be used to improve one or more electrical properties (e.g., charge retention time, charge stability) of memory cells (e.g., DRAM cells), which may, in turn, improve the efficiency, performance, and reliability of memory devices (e.g., DRAM devices) including the memory cells.

The following description provides specific details, such as material types, material thicknesses, and processing conditions in order to provide a thorough description of embodiments of the disclosure. However, a person of ordinary skill in the art will understand that the embodiments of the disclosure may be practiced without employing these specific details. Indeed, the embodiments of the disclosure may be practiced in conjunction with conventional fabrication techniques employed in the industry. In addition, the description provided herein does not form a complete process flow for forming a memory cell, and each of the memory elements, memory cells, and memory devices described below do not form a complete semiconductor device. Only those process acts and structures necessary to understand the embodiments of the disclosure are described in detail below. Additional acts to form the complete semiconductor device may be performed by conventional fabrication techniques. Also note, any drawings accompanying the present application are for illustrative purposes only, and are thus not drawn to scale. Additionally, elements common between figures may retain the same numerical designation.

As used herein, the singular forms “a,” “an,” and “the” are intended to include the plural forms as well, unless the context clearly indicates otherwise.

As used herein, relational terms, such as “first,” “second,” “top,” “bottom,” “upper,” “lower,” “over,” “under,” etc., are used for clarity and convenience in understanding the disclosure and accompanying drawings and do not connote or depend on any specific preference, orientation, or order, except where the context clearly indicates otherwise.

As used herein, the term “substantially,” in reference to a given parameter, property, or condition, means to a degree that one of ordinary skill in the art would understand that the given parameter, property, or condition is met with a small degree of variance, such as within acceptable manufacturing tolerances.

As used herein, the term “substrate” means and includes a foundation material or construction upon which components, such as those within memory cells as well as other semiconductor device structures, are formed. The substrate may be a semiconductor substrate, a base semiconductor material on a supporting structure, a metal electrode, or a semiconductor substrate having one or more materials, structures, or regions formed thereon. The substrate may be a conventional silicon (Si) substrate or other bulk substrate including a semiconductive material. As used herein, the term “bulk substrate” means and includes not only silicon wafers, but also silicon-on-insulative (“SOI”) substrates, such as silicon-on-sapphire (“SOS”) substrates or silicon-on-glass (“SOG”) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. Furthermore, when reference is made to a “substrate” in the following description, previous process stages may have been utilized to form materials, regions, or junctions in or on the base semiconductor structure or foundation.

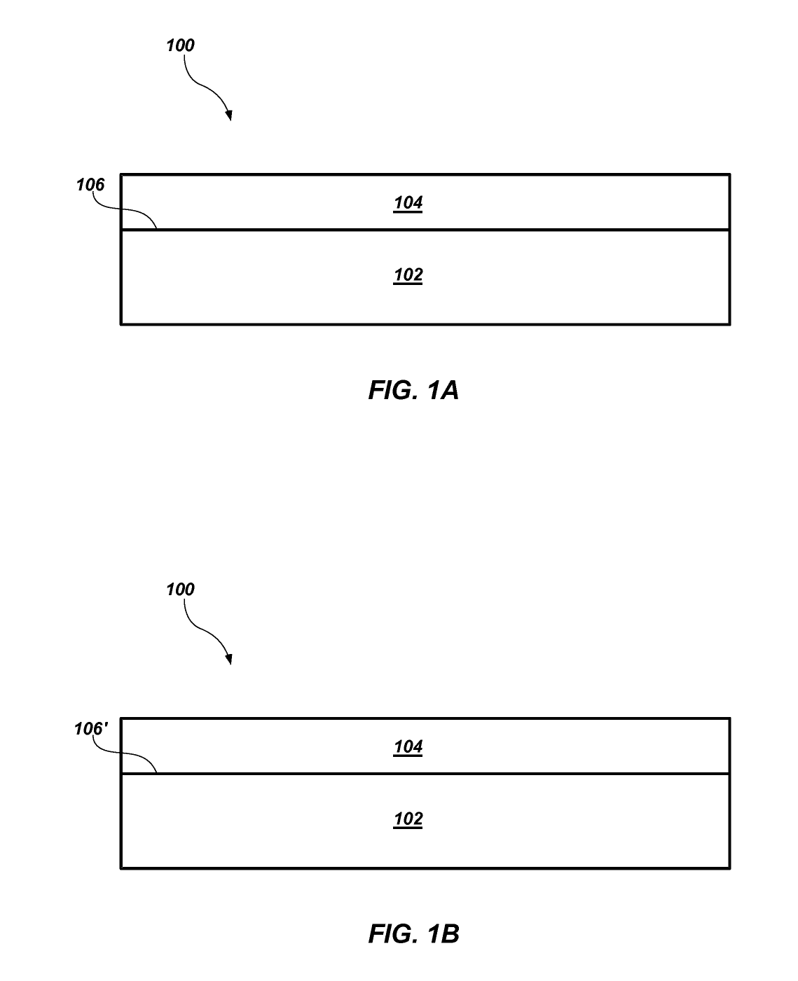

FIGS. 1A and 1B are simplified partial cross-sectional views illustrating embodiments of a method of forming a semiconductor device structure including an insulative material on a semiconductive material. With the description as provided below, it will be readily apparent to one of ordinary skill in the art that the process described herein may be used in various applications. In other words, the process may be used whenever it is desired to modify an interface between an insulative material and a semiconductive material.

Referring to FIG. 1A, a semiconductor device structure 100 may include an insulative material 104 on a semiconductive material 102. An interface 106 may be located between the insulative material 104 and the semiconductive material 102. The semiconductive material 102 may be formed of any material including at least one semiconductive surface upon which the insulative material 104 may be formed. For example, the semiconductive material 102 may be formed of and include a semiconductive element (e.g., an element of Group IV of the Periodic Table of Elements, such as Si, or Ge), a semiconductive compound (e.g., a compound including elements of Group IV of the Periodic Table of Elements, such as Si₁₋ₓGeₓ, where x is, for example, a mole fraction between 0.2 and 0.8; a compound including elements of Groups III and V of the Periodic Table of Elements, such as GaAs, GaN, or InP; a compound including elements of Groups IV and VI of the Periodic Table of Elements), alloys thereof, or combinations thereof. In addition, the semiconductive material 102 may be doped, or may be undoped. By way of non-limiting example, the semiconductive material 102 may comprise a doped or undoped Si material, such as a doped or undoped form of at least one of a monocrystalline Si, polycrystalline Si, and amorphous Si. In some embodiments, the semiconductive material 102 is undoped monocrystalline Si. The semiconductive material 102 may be formed at any desired dimensions. As depicted in FIG. 1A, the semiconductive material 102 may have a substantially planar topography. In additional embodiments, the semiconductive material 102 may have a substantially non-planar topography, wherein the semiconductive material 102 includes at least one elevated region and at least one recessed region. The semiconductive material 102 may comprise a substrate (e.g., a Si substrate), or may be formed in, on, or over a substrate. The semiconductive material 102 may be formed using conventional processes and equipment, which are not described in detail herein.

The insulative material 104 may be formed of and include any electrically insulative material, such as an electrically insulative oxide material. By way of non-limiting example, the insulative material 104 may be a silicon oxide material (e.g., a material including Si atoms and oxygen atoms), such as silicon dioxide (SiO₂), phosphosilicate glass (PSG), borosilicate glass (BSG), borophosphosilicate glass (BPSG), hafnium silicate (HfSiO₄), zirconium silicate (ZrSiO₄), or combinations thereof. In some embodiments, the insulative material 104 is SiO₂. The insulative material 104 may be formed at any suitable thickness. By way of non-limiting example, a thickness of the insulative material 104 may be from about 5 Angstroms (Å) to about 700 Å, such as from about 20 Å to about 250 Å, from about 30 Å to about 150 Å, or from about 45 Å to about 75 Å. In some embodiments, the thickness of the insulative material 104 is from about 45 Å to about 75 Å. The thickness of the insulative material 104 may be substantially uniform, or at least one region of the insulative material 104 may have a different thickness than at least one other region of the insulative material 104.

The insulative material 104 may be formed on the semiconductive material 102 using at least one conventional process, such as a thermal growth process (e.g., a furnace oxidation process, a radical oxidation process), a deposition process (e.g., an atomic layer deposition process, a chemical vapor deposition process, a physical vapor deposition process), or a combination thereof. In some embodiments, the insulative material 104 is thermally grown from the semiconductive material 102. For example, the semiconductive material 102 (e.g., silicon material) may be heated to a temperature of less than or equal to about 1200° C., such as from about 700° C. to about 1000° C., in the presence of an oxidizing species to faun the insulative material 104. The oxidizing species may be a dry oxidizing species (e.g., oxygen gas), a wet oxidizing species (e.g., water vapor), a radical oxidizing species (e.g., an oxygen radical, a hydroxyl radical), or a combination thereof. Thermal growth may terminate after a limiting amount of the insulative material 104 is formed due to an inability of additional oxidizing species to penetrate through the insulative material 104 and react with the underlying semiconductive material 102. In additional embodiments, a deposition process may be used to form the insulative material 104 on the semiconductive material 102. In other embodiments, a portion of the insulative material 104 may be thermally grown from the semiconductive material 102, and a deposition process may be used to form another portion of the insulative material 104 on the thermally grown portion of the insulative material 104.

Forming the insulative material 104 on the semiconductive material 102 may result in the formation of defects at least at the interface 106 between insulative material 104 and the semiconductive material 102. As a non-limiting example, the interface 106 may include dangling bonds (e.g., due to broken bonds between at least one of oxygen atoms and silicon atoms in the insulative material 104 and silicon atoms in the semiconductive material 102, structural defects formed during the formation of the insulative material 104) that may act as charge traps. In addition, while FIG. 1A depicts the interface 106 as a smooth and discrete boundary between the semiconductive material 102 and the insulative material 104, the interface 106 may in fact be rough (e.g., of a nonlinear topography) and may include also a gradual change (e.g., gradient) in relative amounts of the components of the insulative material 104 and the semiconductive material 102 in a boundary region, as opposed to a discrete, step-like change defining a boundary line.

Referring to FIG. 1B, the semiconductor device structure 100 may be subjected to at least one microwave anneal process to at least form a modified interface 106′ between the semiconductive material 102 and the insulative material 104. The modified interface 106′ may exhibit improved characteristics as compared to the interface 106 (FIG. 1A) initially formed between the semiconductive material 102 and the insulative material 104. For example, the modified interface 106′ may exhibit a reduced defect density (e.g., may include fewer defects, such as fewer charge traps) relative to the interface 106 initially formed between the semiconductive material 102 and the insulative material 104. As another example, the modified interface 106′ may provide a smoother and more discrete boundary between the insulative material 104 and the semiconductive material 102 relative to the interface 106 initially formed between the insulative material 104 and the semiconductive material 102. In additional embodiments, the microwave anneal process may also modify one or more characteristics of the insulative material 104. For example, if the insulative material 104 is deposited on the semiconductive material 102, the microwave anneal process may reduce at least some defects (e.g., deviations from crystalline perfection, such as void spaces) within the deposited insulative material 104.

The microwave anneal process may expose the semiconductor device structure 100 to microwave radiation having a frequency, or range of frequencies, within a range of from about 300 megahertz (MHz) to about 300 gigahertz (GHz), such as from about 900 MHz to about 150 GHz, from about 1 GHz to about 50 GHz, or from about 2 GHz to about 25 GHz. The microwave frequency may be fixed or may be variable. In some embodiments, the microwave radiation has a fixed frequency of about 5.8 GHz. In additional embodiments, the microwave radiation has a fixed frequency of about 2.45 GHz. The microwave radiation may be produced by a single source (e.g., a single magnetron, gyroton, traveling wave tube amplifier), or may be produced from multiple sources. If multiple sources of microwave radiation are utilized, the microwave frequency produced by each of the multiple sources may be controlled so as to produce a uniform field of microwave radiation.

The microwave anneal process may employ any power and duration of exposure sufficient to form the modified interface 106′ between the semiconductive material 102 and the insulative material 104. The power and duration of the microwave anneal process employed for a given application may at least partially depend on the microwave frequency (or frequencies) utilized. As a non-limiting example, a power applied to each source of microwave radiation utilized during the microwave anneal process may be within a range of from about 50 watts (W) to about 2500 W, such as from about 400 W to about 2000 W, or from about 600 W to about 1500 W, and a duration of the microwave anneal process may be within a range of from about 2 seconds to about 5 hours. In some embodiments, a power applied to each source of microwave radiation is about 700 W, and a duration of the microwave anneal process is about 15 minutes. For a given microwave frequency, a microwave anneal process using multiple sources of microwave radiations may utilize at least one of a different overall power and a different duration (e.g., increased overall power and decreased duration) as compared to a microwave anneal process utilizing a single source of microwave radiation. For example, a microwave anneal process using eight sources of microwave radiation may utilize an overall power of about 5600 W, whereas a microwave anneal process utilizing a single source of microwave radiation may utilize an overall power of about 700 W.

The microwave anneal process may expose the semiconductor device structure 100 to a single dose of microwave radiation, or may expose the semiconductor device structure 100 to multiple doses of microwave radiation. If multiple doses of microwave radiation are utilized, the initial dose of microwave radiation may partially anneal at least the interface 106 (FIG. 1A) to reduce a defect density thereof, and the at least one other dose of microwave radiation may further anneal at least the interface 106 to further reduce the defect density thereof and form the modified interface 106′. Each of the multiple doses of microwave radiation may be substantially the same (e.g., substantially the same frequency, power, duration), or at least one of the multiple doses may be different than at least one other of the multiple doses (e.g., different frequency, different power, different duration). In some embodiments, the semiconductor device structure 100 is exposed to a single dose of microwave radiation shortly after forming the insulative material 104 on the semiconductive material 102.

During the microwave anneal process, at least a majority of the semiconductor device structure 100 may be maintained at a temperature less than or equal to a decoupling temperature of at least one component (e.g., Si) of the semiconductive material 102. As used herein, the term “decoupling temperature” means and includes the temperature at which a material (e.g., Si) transitions from being coupled with microwave radiation to being decoupled from microwave radiation. In turn, as used herein, the term “couple” means that energy is transferred from microwave radiation to an indicated material, and the term “decouple” means that energy is not transferred from microwave radiation to the indicated material. The microwave radiation of the microwave anneal process may only couple with the at least one component of the semiconductive material 102 (e.g., the microwave radiation may not couple to the insulative material 104), and may only couple with the at least one component up to the decoupling temperature of the at least one component. The microwave radiation may thus only heat at least the majority of the semiconductor device structure 100 (e.g., a majority of the semiconductive material 102, and a majority of the insulative material 104) up to the decoupling temperature of the at least one component. Portions of the semiconductive material 102 and the insulative material 104 more proximate the interface 106 may have a higher temperature (e.g., closer to the decoupling temperature of the at least one component of the semiconductive material 102) than other portions of the semiconductive material 102 and the insulative material 104, such as portions more distal from the interface 106. Furthermore, while the majority of the semiconductor device structure 100 may be maintained at a temperature less than or equal to the decoupling temperature of the at least one component of the semiconductive material 102, the characteristics of the interface 106 may result in localized heating (e.g., resistive heating) above the decoupling temperature of the at least one component in regions of the semiconductor device structure 100 directly proximate the interface 106 (e.g., less than or equal to about 15 Angstroms from the interface 106).

By way of non-limiting example, if the semiconductive material 102 includes an Si material (e.g., at least one of monocrystalline Si, polycrystalline Si, and amorphous Si) the decoupling temperature of the Si of the semiconductive material 102 may be less than or equal to about 550° C., such as less than or equal to about 500° C., less than or equal to about 450° C., less than or equal to about 400° C., or less than or equal to about 350° C. Accordingly, at least the majority of the semiconductor device structure 100 may be maintained at a temperature less than or equal to about 550° C. during the microwave anneal process, such as less than or equal to about 500° C., less than or equal to about 450° C., less than or equal to about 400° C., or less than or equal to about 350° C. In some embodiments, at least the majority of the semiconductor device structure 100 is maintained at a temperature less than or equal to about 550° C. during the microwave anneal process.

Use of the disclosed microwave anneal process may maintain the semiconductor device structure 100 at a relatively low temperature as compared to many conventional processes (e.g., high-temperature thermal anneal processes) used to improve characteristics of an interface between a semiconductive material and an insulative material. Accordingly, the microwave anneal process of the disclosure may enable fabrication of the semiconductor device structure 100 at a lower total thermal budget (e.g., enabling the incorporation of less thermally stable materials, such as photoresist materials, in the semiconductor device structure 100), and may mitigate problems (e.g., structural deformations, undesired material diffusion) that may otherwise result from exposing the semiconductor device structure 100 to higher temperatures to improve the characteristics of the interface 106. Alternatively, use of the disclosed microwave anneal process may, for a given thermal budget for a semiconductor device structure, enable use of fabrication process acts which, when conventional thermal anneal processes are employed, may be impractical to implement as the thermal budget would be exceeded.

The microwave anneal process may be performed under any suitable ambient conditions. For example, the microwave anneal process may be performed in an inert atmosphere, such as a nitrogen (N₂) atmosphere. In addition, the microwave anneal process may utilize any suitable pressure, or range of pressures. For example, the microwave anneal process may be performed at about atmospheric pressure.

Accordingly, a method of forming a semiconductor device structure comprises forming an insulative material on a semiconductive material, and microwave annealing at least an interface between the insulative material and the semiconductive material.

Furthermore, a semiconductor device structure of the disclosure comprises a semiconductive material, an insulative material on the semiconductive material, and a modified interface between the semiconductive material and the insulative material, the modified interface formed by subjecting an initial interface between the semiconductive material and the insulative material to at least one microwave anneal process.

Following the formation of the modified interface 106′, the semiconductor device structure 100 may be subjected to additional processing. By way of non-limiting example, one or more materials may be formed on or over the insulative material 104. The semiconductor device structure 100 may also be subjected to one or more patterning, removal, doping, and passivation processes. Such additional processing may be performed using conventional processes and equipment, which are not described in detail herein.

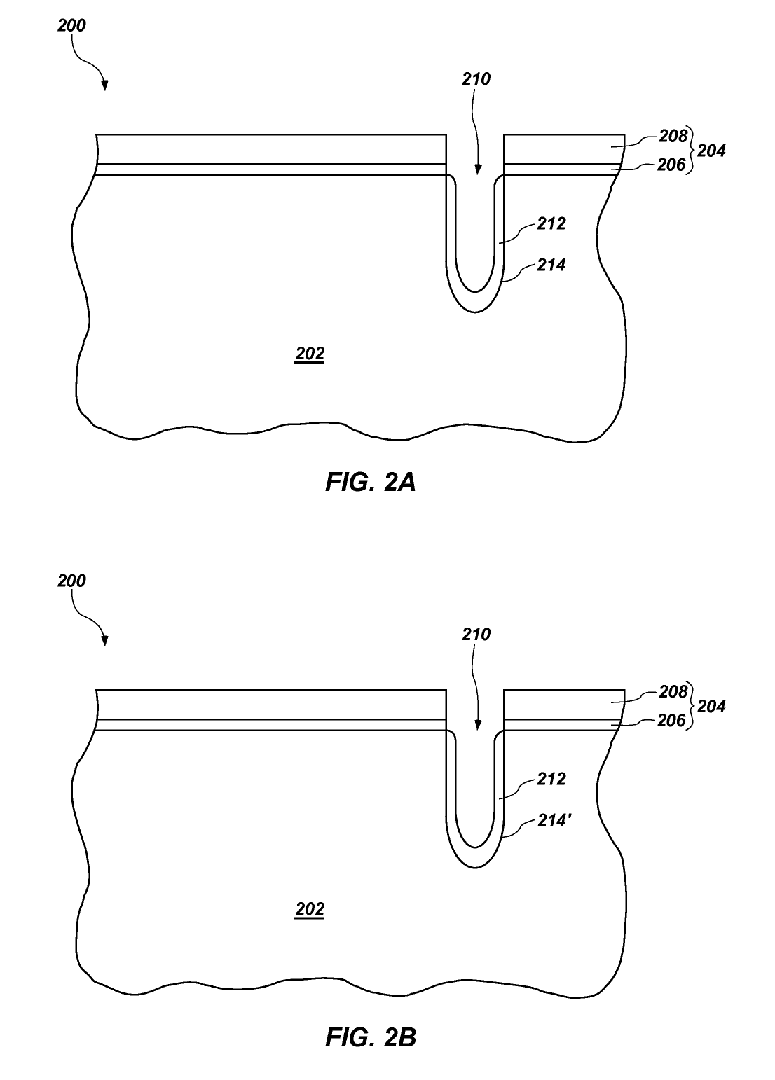

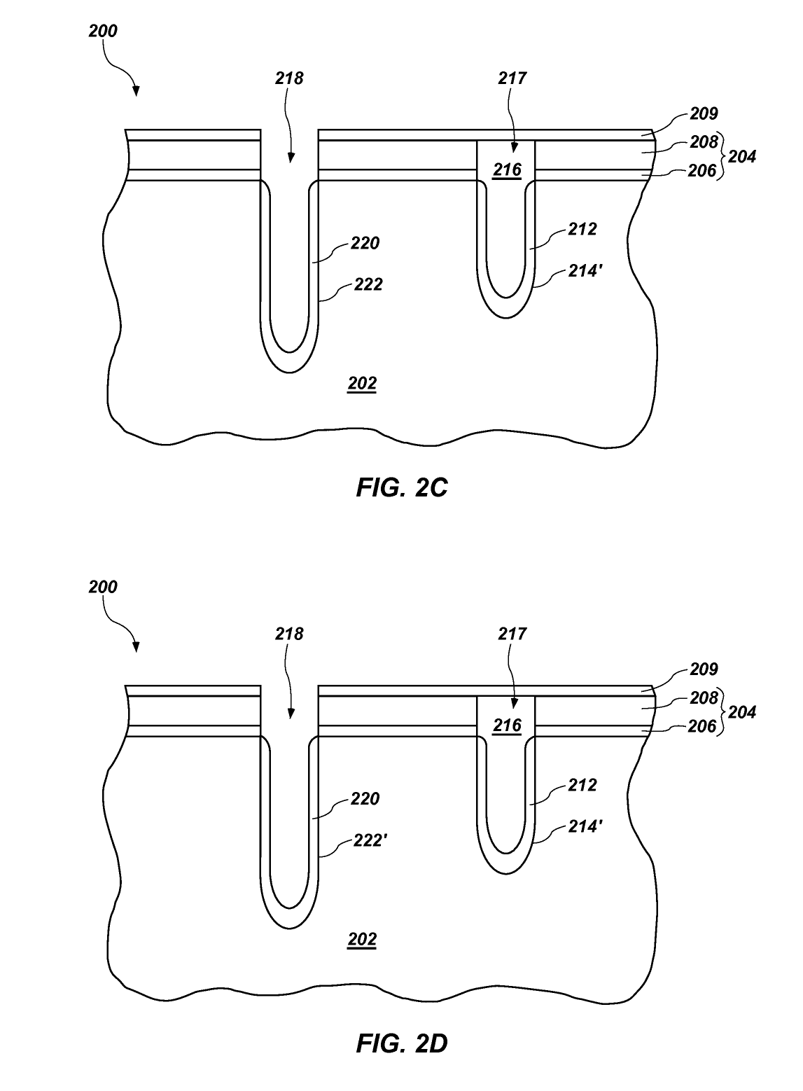

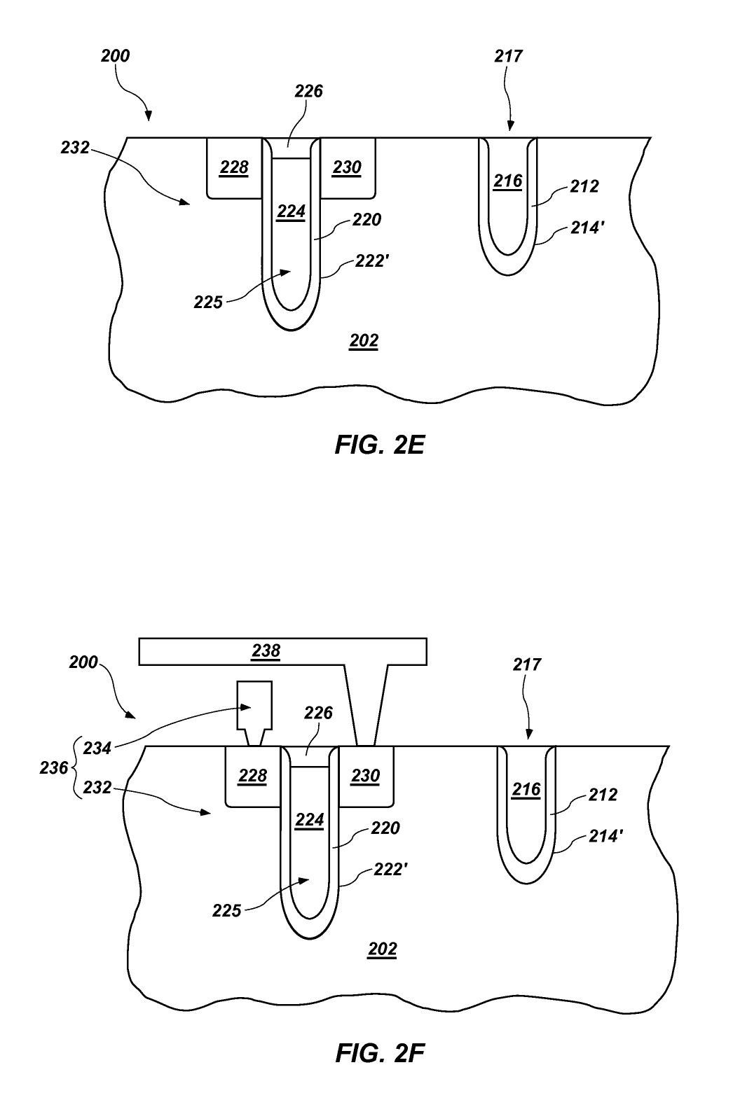

FIGS. 2A through 2F are simplified partial cross-sectional views illustrating embodiments of a method of forming another semiconductor device structure, such as a memory device structure, including at least one insulative material on a semiconductive material. Referring to FIG. 2A, a semiconductor device structure 200 may include a semiconductive material 202, a hard mask 204 over the semiconductive material 202, and at least one isolation recess 210 (e.g., opening) extending through the hard mask 204 and into the semiconductive material 202. An insulative material 212 may be located at least on surfaces of the semiconductive material 202 within the isolation recess 210. As depicted in FIG. 2A, in some embodiments, the insulative material 212 is substantially limited to surfaces of the semiconductive material 202 within the isolation recess 210. While not shown, in additional embodiments, the insulative material 212 may be located on the surfaces of the semiconductive material 202 within the isolation recess 210, and on surfaces of the hard mask 204 (e.g., surfaces of the hard mask 204 within the isolation recess 210).

The semiconductive material 202 may be substantially similar to the semiconductive material 102 previously described with reference to FIG. 1A. In some embodiments, the semiconductive material 202 is undoped monocrystalline Si. The hard mask 204 may be formed of and include at least one hard mask material, such as at least one of Si, a silicon oxide, a silicon nitride, a silicon oxycarbide, aluminum oxide, and a silicon oxynitride. For example, as depicted in FIG. 2A, the hard mask 204 may include a pad oxide material 206 (e.g., SiO₂) on the semiconductive material 202, and a silicon nitride material 208 on the pad oxide material 206. The semiconductive material 202, the hard mask 204, and the isolation recess 210 may be formed using conventional processes and equipment, which are not described in detail herein.

The insulative material 212 may be substantially similar to the insulative material 104 previously described with respect to FIG. 1A. In some embodiments, the insulative material 212 is SiO₂. In additional embodiments, such as where the insulative material 212 is formed on surfaces of the semiconductive material 202 within the isolation recess 210 and on surfaces of the hard mask 204 within the isolation recess 210, at least one region of the insulative material 212 may have a different material composition than at least one other region of the insulative material 212. For example, if the semiconductive material 202 is formed of and includes undoped monocrystalline Si, and the hard mask 204 is formed of and includes silicon nitride, regions of the insulative material 212 on the semiconductive material 202 may be formed of and include SiO₂, and other regions of the insulative material 212 on the silicon nitride of the hard mask 204 may be formed of and include silicon oxynitride. An interface 214 between the insulative material 212 and the semiconductive material 202 may be substantially similar to the interface 106 between the insulative material 104 and the semiconductive material 102 previously described with respect to FIG. 1A. For example, similar to the interface 106 previously described, the interface 214 may include a number of defects (e.g., charge traps).

The insulative material 212 may be formed on at least the surfaces of the semiconductive material 202 within the isolation recess 210 using conventional processes, such as those previously described with respect to forming the insulative material 104 on the semiconductive material 102. The insulative material 212 may, for example, be formed on at least the surfaces of the semiconductive material 202 within the isolation recess 210 using at least one of a thermal growth process (e.g., a furnace oxidation process, a radical oxidation process), and a deposition process. By way of non-limiting example, the insulative material 212 may be formed using a thermal growth process that includes exposing the semiconductor device structure 200 to at least one of a dry oxidizing species (e.g., oxygen gas) and a wet oxidizing species (e.g., water vapor) at a suitable elevated temperature (e.g., less than or equal to about 1000° C.). In some embodiments, the insulative material 212 is formed on surfaces of the semiconductive material 202 within the isolation recess 210 using a furnace oxidation process that includes exposing the semiconductive material 202 to oxygen gas at a temperature of about 900° C.

Referring to FIG. 2B, the semiconductor device structure 200 may be subjected to at least one microwave anneal process to form at least a modified interface 214′ between the semiconductive material 202 and the insulative material 212. The modified interface 214′ may be substantially similar to the modified interface 106′ previously described with respect to FIG. 1B. For example, the modified interface 214′ may exhibit a reduced defect density as compared to the initial interface 214 (FIG. 2A), and the modified interface 214′ may provide a smoother and more discrete boundary between the insulative material 212 and the semiconductive material 202 as compared to the initial interface 214 between the insulative material 212 and the semiconductive material 202. In additional embodiments, the microwave anneal process may also modify one or more characteristics of the insulative material 212. For example, if the insulative material 212 is deposited on the semiconductive material 202, the microwave anneal process may reduce at least some defects (e.g., deviations from crystalline perfection, such as void spaces) within the deposited insulative material 212. The microwave anneal process may be substantially similar to the microwave anneal process previously described with respect to FIG. 1B.

Accordingly, a method of forming a semiconductor device structure comprises forming an insulative material on surfaces of a semiconductive material within at least one recess. An interface between the insulative material and the semiconductive material is exposed to microwave radiation to form a modified interface between the insulative material and the semiconductive material.

In additional embodiments, the microwave anneal process used to form the modified interface 214′ between the semiconductive material 202 and the insulative material 212 may be conducted at a later stage of processing. For example, the semiconductor device structure 200 may instead be subjected to at least one microwave anneal process at one or more later processing stages (e.g., following formation of another insulative material in another recess), as described in further detail below. In yet additional embodiments, the microwave anneal process may be used to form the modified interface 214′ between the semiconductive material 202 and the insulative material 212, and the semiconductor device structure 200 may be subjected to at least one additional microwave anneal process at one or more later processing stages, as described in further detail below.

Referring to FIG. 2C, after forming the modified interface 214′, the semiconductor device structure 200 may be subjected to additional processing. For example, remaining open space of the isolation recess 210 (FIG. 2B) may be filled with an isolation material 216 to form an isolation structure 217 including the insulative material 212 and the isolation material 216, a photoresist material 209 may be formed over surfaces of the hard mask 204 and the isolation material 216, an access device recess 218 extending through the photoresist material 209, and the hard mask 204, and into the semiconductive material 202 may be formed adjacent the isolation structure 217, and another insulative material 220 may be formed on at least surfaces of the semiconductive material 202 within the access device recess 218. As depicted in FIG. 2C, the another insulative material 220 may be substantially limited to surfaces of the semiconductive material 202 within the access device recess 218. While not shown, in additional embodiments, the another insulative material 220 may be formed on the surfaces of the semiconductive material 202 within the access device recess 218 and on surfaces of at least one additional material (e.g., surfaces of the hard mask 204 and the photoresist material 209 within the access device recess 218).

The isolation material 216 may comprise a conventional dielectric material including, but not limited to, SiO₂. The photoresist material 209 may be a conventional photoresist material facilitating the formation of the access device recess 218 by way of a conventional material removal process (e.g., a dry etching process, a wet etching process). The isolation material 216, the photoresist material 209, and the access device recess 218 may be formed using conventional processes and equipment, which are not described in detail herein.

The another insulative material 220 may be substantially similar to the insulative material 104 previously described with respect to FIG. 1A. In some embodiments, the another insulative material 220 is SiO₂. While not shown, in additional embodiments, such as where the another insulative material 220 is formed on surfaces of the semiconductive material 202 within the access device recess 218 and on surfaces of at least one additional material (e.g., surfaces of the photoresist material 209 and the hard mask 204 within the access device recess 218), at least one region of the another insulative material 220 may have a different material composition than at least one other region of the another insulative material 220. An interface 222 between the another insulative material 220 and the semiconductive material 202 may be substantially similar to the interface 106 between the insulative material 104 and the semiconductive material 102 previously described with respect to FIG. 1A. For example, similar to the interface 106 previously described, the interface 222 may include a number of defects (e.g., charge traps).

The another insulative material 220 may be formed on at least the surfaces of the semiconductive material 202 within the access device recess 218 using conventional processes, such as those previously discussed with respect to forming the insulative material 104 on the semiconductive material 102. The another insulative material 220 may, for example, be formed on at least the surfaces of the semiconductive material 202 within the access device recess 218 using at least one of a thermal growth process (e.g., a furnace oxidation process, a radical oxidation process), and a deposition process. As a non-limiting example, the another insulative material 220 may be formed using a thermal growth process that includes exposing the semiconductor device structure to at least one of a dry oxidizing species (e.g., oxygen gas), a wet oxidizing species (e.g., water vapor), and a radical oxidizing species (e.g., an oxygen radical, a hydroxyl radical) at a suitable elevated temperature (e.g., less than or equal to about 1000° C.). In some embodiments, the another insulative material 220 is formed on surfaces of the semiconductive material 202 within the access device recess 218 using a radical oxidation process (e.g., an in situ steam generation (ISSG) process) including exposing the semiconductor device structure 200 to water vapor at a temperature of about 1000° C.

Referring to FIG. 2D, the semiconductor device structure 200 may, optionally, be subjected to at least one additional microwave anneal process to form at least a modified interface 222′ between the semiconductive material 202 and the another insulative material 220. If the additional microwave anneal process is performed, the modified interface 222′ may be substantially similar to the modified interface 106′ previously described with respect to FIG. 1B. For example, the modified interface 222′ may have a reduced defect density as compared to the initial interface 222 (FIG. 2C), and the modified interface 222′ may be a smooth and discrete boundary between the another insulative material 220 and the semiconductive material 202 as compared to the initial interface 222 between the another insulative material 220 and the semiconductive material 202. In additional embodiments, the additional microwave anneal process may also modify one or more characteristics of the another insulative material 220. For example, if the another insulative material 220 is deposited on the semiconductive material 202, the microwave anneal process may reduce at least some defects (e.g., deviations from crystalline perfection, such as void spaces) within the another insulative material 220. The additional microwave anneal process may be substantially similar to the microwave anneal process previously described with respect to FIG. 1B. In some embodiments, the additional microwave anneal process is omitted and the modified interface 222′ between the semiconductive material 202 and the another insulative material 220 is not formed.

Referring to FIG. 2E, after forming the another insulative material 220, and, optionally, the modified interface 222′ between the another insulative material 220 and the semiconductive material 202, the semiconductor device structure 200 may be subjected to further processing (e.g., conventional deposition processes, patterning processes, removal processes) to remove the photoresist material 209 (FIG. 2D), the hard mask 204 (FIG. 2D), and a portion of the isolation structure 217, and to form a recessed access device 232 (e.g., a transistor). The recessed access device 232 may include the another insulative material 220, a conductive material 224 over a lower portion of the another insulative material 220 in the access device recess 218 (FIG. 2D), an additional insulative material 226 over the conductive material 224 and an upper portion of the another insulative material 220 in the access device recess 218, and a source region 228 and a drain region 230 in the semiconductive material 202 and laterally adjacent sides of the another insulative material 220.

The conductive material 224 may be formed of and include any suitable electrically conductive material including, but not limited to, a metal (e.g., tungsten, titanium, nickel, platinum, gold), a metal alloy, a metal-containing material (e.g., metal nitrides, metal silicides, metal carbides, metal oxides), a conductively doped semiconductor material (e.g., conductively doped silicon, conductively doped germanium, etc.), or combinations thereof. The conductive material 224 may form a word line extending in and out of the page relative to the cross-section shown in FIG. 2E. The portion of the conductive material 224 within the cross-section illustrated in FIG. 2E may be considered to be a gate 225 of the recessed access device 232. The conductive material 224 may be formed using conventional processes and equipment, which are not described in detail herein.

The additional insulative material 226 may be formed of and include any suitable electrically insulative material including, but not limited to, SiO₂, silicon nitride, PSG, BPSG, fluorosilicate glass, or combinations thereof. The additional insulative material 226 may be formed using conventional processes and equipment, which are not described in detail herein.

The source region 228 and a drain region 230 in the semiconductive material 202 may each include a dopant facilitating a desired conductivity. For example, each of the source region 228 and the drain region 230 may be doped with arsenic ions or phosphorous ions to facilitate a desired n-type conductivity. As another example, each of the source region 228 and the drain region 230 may be doped with boron ions to facilitate a desired p-type conductivity. The conductivity of the source region 228 may be the same as the conductivity of the drain region 230, or the conductivity of the source region 228 may be different than the conductivity of the drain region 230 (e.g., the source region 228 and the drain region 230 may have different n-type conductivities, or the source region 228 and the drain region 230 may have different p-type conductivities). The source region 228 and a drain region 230 may be formed using conventional processes and equipment, which are not described in detail herein.

Accordingly, a method of forming a semiconductor device structure comprises forming at least one isolation recess in a semiconductive material. An insulative material is formed on surfaces of the semiconductive material within the isolation recess. An interface between the insulative material and the semiconductive material is exposed to microwave radiation. Remaining open space of the at least one isolation recess is filled with a dielectric material to form at least one isolation structure. A recessed access device is formed in the semiconductive material adjacent the at least one isolation structure.

Furthermore, a semiconductor device structure of the disclosure comprises at least one isolation structure in a semiconductive material, a modified interface between an insulative material of the at least one isolation structure and the semiconductive material, the modified interface formed by exposing an initial interface between the insulative material and the semiconductive material to microwave radiation, and a recessed access device in the semiconductive material adjacent the at least one isolation structure.

Referring to FIG. 2F, one of the source region 228 and the drain region 230 of the recessed access device 232 may be electrically connected to a storage device 234 to form a memory cell 236, such as a DRAM cell, including the recessed access device 232 and the storage device 234. The storage device 234 may be a capacitive structure having a suitably large capacitance to enable a signal to be communicated to one or more peripheral circuits (not shown) by the recessed access device 232. The storage device 234 may, for example, include three-dimensional capacitive structures, such as trench and stacked capacitive structures. The storage device 234 may be formed using conventional processes and equipment, which are not described in detail herein.

The memory cell 236 may exhibit reduced current leakage and increased retention time, and may require fewer clock cycles devoted to refresh as compared to a conventional memory cell produced without utilizing the methods of the disclosure to form at least one of the modified interface 214′ between the semiconductive material 202 and the insulative material 212, and the modified interface 222′ between the semiconductive material 202 and the another insulative material 220. In addition, the retention time of the memory cell 236 may be substantially more stable (e.g., less variable) relative to that of a conventional memory cell. As a non-limiting example, the memory cell 236 may have at least a two-time (2×) reduction in variable retention time (VRT) as compared to a conventional memory cell produced without utilizing the methods of the disclosure. Accordingly, a memory device comprising a large number of memory cells 236 fabricated using a method of the disclosure will enable less frequent refreshes as compared to memory devices comprising memory cells fabricated using conventional processing.

With continued reference to FIG. 2F, the other of the source region 228 and the drain region 230 may be electrically connected to a conductive structure 238. The conductive structure 238 may be formed of and include any suitable electrically conductive material including, but not limited to, a metal (e.g., tungsten, titanium, nickel, platinum, gold), a metal alloy, a metal-containing material (e.g., metal nitrides, metal silicides, metal carbides, metal oxides), a conductively doped semiconductor material (e.g., conductively doped silicon, conductively doped germanium), or combinations thereof. The conductive structure 238 may be a bit line extending in a direction substantially perpendicular to that of the conductive material 224 (e.g., which, as previously discussed, may be a word line). The conductive structure 238 may be formed using conventional processes and equipment, which are not described in detail herein.

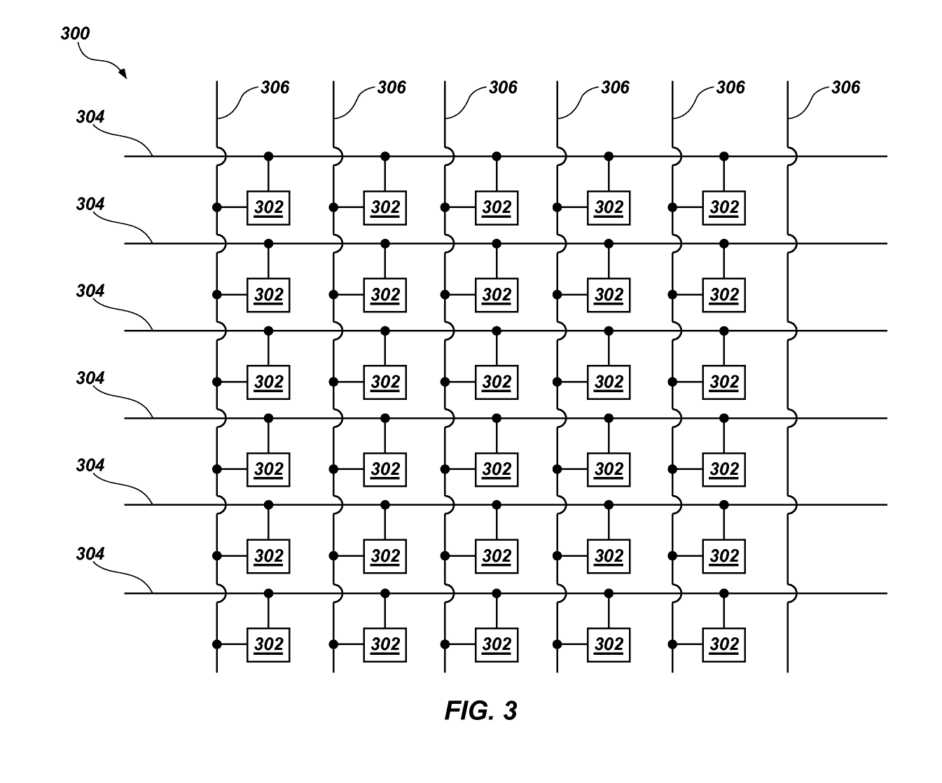

FIG. 3 is a partial schematic view illustrating a memory array 300, such as a DRAM array. The memory array 300 may include memory cells 302 connected to word lines 304 and bit lines 306. Each of the memory cells 302, each of the word lines 304, and each of the bit lines 306 may, respectively, be substantially similar to the memory cell 236, the conductive material 224, and the conductive structure 238 previously described with reference to FIGS. 2E and 2F. The word lines 304 and the bit lines 306 may cooperatively form address lines, which may be electrically connected to at least one peripheral circuit (not shown), as described in further detail below. Although a single memory array 300 is shown in FIG. 3, one of ordinary skill in the art will understand that the memory array 300 may be segregated into multiple banks, with each bank having dedicated input and output ports further coupled to a common internal bus, so that information may be written and accessed from different banks sequentially or simultaneously.

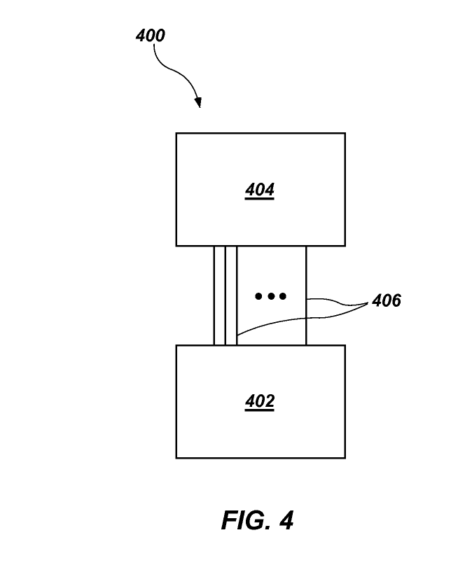

FIG. 4 is a diagrammatic view illustrating a memory device 400, such as a DRAM device. The memory device 400 may include at least one memory array 402 connected to at least one peripheral circuit 404 by way of control lines 406. The memory array 402 may be substantially similar to the memory array 300 previously described with respect to FIG. 3. The peripheral circuit 404 may include circuits configured to address memory cells (not shown) within the memory array 402 so that information may be stored and accessed. The peripheral circuits 404 may, for example, include sense amplifiers, suitable multiplexing and de-multiplexing circuits, latching circuits, buffer circuits, and input and output circuits configured to communicate with other external devices (not shown). The peripheral circuit 404 may also include various circuits operable to supply and regulate power to the memory device 400. The control lines 406 may be connected to address lines (not shown) within the memory array 402. The peripheral circuit 404 and the control lines 406 may be formed using conventional processes and equipment, which are not described in detail herein.

The memory device 400 may have improved reliability, performance, and durability as compared to a conventional memory device formed without using the methods of the disclosure. For example, for a given number of refresh cycles, the memory device 400 may include fewer memory cells having unsatisfactory refresh properties (e.g., a reduced number of refresh-based memory cell failures throughout the memory array 402), and may include fewer memory cells having unsatisfactory speed properties (e.g., a reduced number of speed-based memory cell failures throughout the memory array 402) as compared to a conventional memory device. In some embodiments, for a given number of refresh cycles, the memory device 400 includes both a reduced number of refresh-based memory cell failures and a reduced number of speed-based memory cell failures as compared to memory devices not formed using the methods of the disclosure. In contrast, many conventional fabrication methods resulting in a reduced number of refresh-based memory cell failures also result in an increased number of speed-based memory cell failures, and vice versa. In addition, for a given number of refresh cycles, the memory device 400 may have reduced retention time variability (e.g., may have increased retention time consistency) across the memory cells of the memory array 402 as compared to a conventional memory device.

Accordingly, a semiconductor device of the disclosure comprises a memory array comprising memory cells connected to word lines and bit lines, and peripheral circuitry electrically connected to the memory array. Each of the memory cells is formed by the method comprising forming at least one isolation structure in a semiconductive material, forming a recessed access device in the semiconductive material adjacent the at least one isolation structure, and electrically connecting the recessed access device to a storage device. A modified interface is between an insulative material of the at least one isolation structure and the semiconductive material, the modified interface formed by exposing an initial interface between the insulative material and the semiconductive material to microwave radiation.

The methods of the disclosure may effectively reduce defects (e.g., interfacial charge traps) in semiconductor device structures 100, 200 including an insulative material 104, 212, 220 on a semiconductive material 102, 202. The microwave anneal processes of the disclosure may improve the electrical properties the semiconductor device structures 100, 200 while avoiding the problems (e.g., energetic inefficiencies, structural deformations, undesired material diffusion) associated with many conventional processes (e.g., high temperature anneal processes) used to fabricate similar semiconductor device structures. The semiconductor device structures 100, 200 may, in turn, improve one or more properties of devices into which they are at least partially incorporated. Memory cells formed by the methods of the disclosure may have improved retention time and retention time stability as compared to many conventional memory cells. In addition, memory devices including memory arrays formed using the methods of the disclosure may have fewer memory cell failures and increased retention time consistency across the array of memory cells as compared to many conventional memory devices.

The following example serves to explain some embodiments of the disclosure in more detail. The example is not to be construed as being exhaustive or exclusive as to the scope of the disclosure.

### EXAMPLE

A number of sample memory devices, each including a two gigabyte memory array (e.g., a memory array including 2×10⁹ memory cells), were fabricated and subsequently analyzed. In fabricating the sample memory devices, isolation structures and recessed access devices each including SiO₂ on surfaces of monocrystalline silicon were formed using different methods. For some of the sample memory devices, an interface between the monocrystalline silicon and the SiO₂ of each of the isolation structures was subjected to a microwave anneal (MWA) process immediately after the formation of the SiO₂. In addition, for some of the sample memory devices, an interface between the monocrystalline silicon and the SiO₂ of each of the recessed access devices was subjected to another MWA process immediately after the formation of the SiO₂. The MWA processes included exposing the target interface to microwave radiation (e.g., produced from six sources running at 700 W) having a fixed frequency of about 5.8 GHz for about 15 minutes in an N₂ atmosphere within an AXOM 300 microwave reactor (available from DSG Technologies, Morgan Hill, Calif.). A control sample memory device was fabricated without performing at least one MWA process (e.g., without subjecting the interface between the monocrystalline silicon and the SiO₂ of each isolation structure to a MWA process, and without subjecting the interface between the monocrystalline silicon and the SiO₂ of each recessed access device to another MWA process).

Performing at least one MWA process to modify an interface between SiO₂ (e.g., the SiO₂ incorporated into the isolation structures, and/or the SiO₂ incorporated into the recessed access devices) and monocrystalline silicon reduced retention time variance by at least about 23 percent, decreased an amount of refresh-based memory cell failures by at least about 7 percent, and decreased an amount of speed-based memory cell failures by at least about 6 percent for the sample memory devices as compared to the control sample memory device. As a non-limiting example, a sample memory device subjected to a single MWA process immediately after forming the SiO₂ of each of the isolation structures exhibited a reduction in retention time variance of about 44 percent, a reduction in refresh-based memory cell failures of about 23 percent, and a reduction in speed-based memory cell failures of about 14 percent as compared to the control sample memory device. As another non-limiting example, another sample memory device subjected to a MWA process immediately after forming the SiO₂ of each of the isolation structures and subjected to another MWA process immediately after forming the SiO₂ of each of the recessed access devices exhibited a reduction in retention time variance of about 47 percent, a reduction in refresh-based memory cell failures of about 31 percent, and a reduction in speed-based memory cell failures of about 47 percent as compared to the control sample memory device.

While the disclosure is susceptible to various modifications and alternative forms, specific embodiments have been shown by way of example in the drawings and have been described in detail herein. However, the disclosure is not intended to be limited to the particular forms disclosed. Rather, the disclosure is to cover all modifications, equivalents, and alternatives falling within the scope of the disclosure as defined by the following appended claims and their legal equivalents.

What is claimed is:

1. A method of forming a semiconductor device structure, comprising:
forming an insulative material on a semiconductive material; and
microwave annealing at least an interface between the insulative material and the semiconductive material.

2. The method of claim 1, wherein forming an insulative material on a semiconductive material comprises forming an oxide material on a silicon material.

3. The method of claim 1, wherein forming an insulative material on a semiconductive material compromises forming a silicon oxide material on a silicon material.

4. The method of claim 1, wherein forming an insulative material on a semiconductive material compromises forming silicon dioxide on at least one of monocrystalline silicon, polycrystalline silicon, and amorphous silicon.

5. The method of claim 1, wherein forming an insulative material on a semiconductive material compromises thermally growing the insulative material on the semiconductive material.

6. The method of claim 1, wherein forming an insulative material on a semiconductive material compromises depositing the insulative material on the semiconductive material.

7. The method of claim 1, wherein microwave annealing at least an interface between the insulative material and the semiconductive material comprises coupling microwave radiation with at least one component of the semiconductive material.

8. The method of claim 7, wherein coupling microwave radiation with at least one component of the semiconductive material comprises controlling the microwave radiation so that a majority of the insulative material and the semiconductive material does not exceed a decoupling temperature of the at least one component of the semiconductive material.

9. The method of claim 1, wherein microwave annealing at least an interface between the insulative material and the semiconductive material comprises exposing the interface to a fixed frequency of microwave radiation.

10. The method of claim 1, wherein microwave annealing at least an interface between the insulative material and the semiconductive material comprises exposing the interface to a variable frequency of microwave radiation.

11. The method of claim 1, wherein microwave annealing at least an interface between the insulative material and the semiconductive material comprises exposing the interface to microwave radiation having a frequency within a range of from about 900 MHz to about 150 GHz.

12. The method of claim 1, wherein microwave annealing at least an interface between the insulative material and the semiconductive material comprises exposing the interface to a uniform field of microwave radiation.

13. The method of claim 1, wherein microwave annealing at least an interface between the insulative material and the semiconductive material comprises exposing the interface to a single dose of microwave radiation.

14. The method of claim 1, wherein microwave annealing at least an interface between the insulative material and the semiconductive material comprises exposing the interface to multiple doses of microwave radiation.

15. The method of claim 1, wherein microwave annealing at least an interface between the insulative material and the semiconductive material comprises exposing the interface to microwave radiation for a sufficient amount of time to reduce a defect density at the interface.

16. A method of forming a semiconductor device structure, comprising:
forming an insulative material on surfaces of a semiconductive material within at least one recess; and
exposing an interface between the insulative material and the semiconductive material to microwave radiation to form a modified interface between the insulative material and the semiconductive material.

17. The method of claim 16, wherein forming an insulative material on surfaces of a semiconductive material within at least one recess comprises exposing the surfaces of the semiconductive material to at least one of a furnace oxidation process and a radical oxidation process.

18. The method of claim 16, wherein exposing an interface between the insulative material and the semiconductive material to microwave radiation comprises exposing the interface to microwave radiation having a frequency of about 5.8 GHz or about 2.45 GHz.

19. The method of claim 16, wherein exposing an interface between the insulative material and the semiconductive material to microwave radiation comprises controlling the microwave radiation so that a temperature of a majority of the insulative material and the semiconductive material does not exceed about 550° C.

20. The method of claim 16, further comprising:
forming at least one additional recess extending into the semiconductive material; and
forming another insulative material on additional surfaces of the semiconductive material within the at least one additional recess.

21. The method of claim 20, further comprising exposing another interface between the another insulative material and the semiconductive material to additional microwave radiation to form another modified interface between the another insulative material and the semiconductive material.

22. A method of forming a semiconductor device structure, comprising:
forming at least one isolation recess in a semiconductive material;
forming an insulative material on surfaces of the semiconductive material within the at least one isolation recess;
exposing an interface between the insulative material and the semiconductive material to microwave radiation;
filling remaining open space of the at least one isolation recess with a dielectric material to form at least one isolation structure; and
forming a recessed access device in the semiconductive material adjacent the at least one isolation structure.

23. The method of claim 22, wherein forming a recessed access device in the semiconductive material adjacent the at least one isolation structure comprises:
forming an access device recess in the semiconductive material;
forming another insulative material on surfaces of the semiconductive material within the access device recess;
exposing an interface between the another insulative material and the semiconductive material to additional microwave radiation;
forming a conductive material on the another insulative material; and
forming a source region and a drain region in the semiconductive material adjacent the another insulative material.

24. A semiconductor device structure, comprising:
a semiconductive material;
an insulative material on the semiconductive material; and
a modified interface between the semiconductive material and the insulative material, the modified interface formed by subjecting an initial interface between the semiconductive material and the insulative material to at least one microwave anneal process.

25. A semiconductor device structure, comprising:
at least one isolation structure in a semiconductive material;
a modified interface between an insulative material of the at least one isolation structure and the semiconductive material, the modified interface faulted by exposing an initial interface between the insulative material and the semiconductive material to microwave radiation; and
a recessed access device in the semiconductive material adjacent the at least one isolation structure.

26. A semiconductor device, comprising:
a memory array comprising memory cells connected to word lines and bit lines, each of the memory cells formed by the method comprising:
forming at least one isolation structure in a semiconductive material, a modified interface between an insulative material of the at least one isolation structure and the semiconductive material, the modified interface formed by exposing an initial interface between the insulative material and the semiconductive material to microwave radiation;
forming a recessed access device in the semiconductive material adjacent the at least one isolation structure; and
electrically connecting the recessed access device to a storage device; and
peripheral circuitry electrically connected to the memory array.
